(19) United States
(12) Patent Application Publication
(10) Pub. No.: US 2005/0285208 A1
(43) Pub. Date: Dec. 29, 2005

(54) Metal gate electrode for semiconductor devices

(76) Inventors: Chi Ren, Singapore (SG); Hongyu Yu, Singapore (SG); Siu Hung Daniel Chan, Singapore (SG); Ming-Fu Li, Singapore (SG); Dim-Lee Kwong, Austin, TX (US)

Correspondence Address: DINSMORE & SHOHL LLP;One Dayton Centre, Suite 1300, One South Main Street, Dayton, OH, 45402-2023, US

(21) Appl. No.: 11/149,975

(22) Filed: Jun. 10, 2005

Related U.S. Application Data
(60) Provisional application No. 60/582,547, filed on Jun. 25, 2004.

(51) Int. Cl. H01L 29/76

(52) U.S. Cl. 257/388

(57) ABSTRACT

A gate electrode for semiconductor devices, the gate electrode comprising a mixture of a metal having a work function of about 4 eV or less and a metal nitride.

### CROSS-REFERENCE TO RELATED APPLICATION

This application claims benefit and priority from U.S. provisional patent application No. 60/582,547, filed on Jun. 25, 2004, the contents of which are incorporated herein by reference.

### FIELD OF INVENTION

The present invention relates to a gate electrode for semiconductor devices and to a method of fabricating a gate electrode for semiconductor devices. The present invention will be described herein with reference to novel metal gate electrodes and their methods of fabrication.

### BACKGROUND

Metal gate electrodes will increasingly be used in semiconductor devices such as Complimentary Metal Oxide Semiconductor (CMOS) devices due to poly-silicon depletion effects and dopant penetration effects associated with using poly-silicon material for gate electrodes which are especially serious when the effective gate-oxide thickness (EOT) in a CMOS device is downscaled into the sub-1 nm region.

It has been found that the optimised gate work functions derived to maximise drive current for p-Metal Oxide Semiconductor Field Effect Transistor (p-MOSFETs) and n-MOSFETs with <50 nm gate lengths are respectively about 0.2 eV below the valence band edge and about 0.2 eV above the conduction band edge of silicon (Si). On the other hand, good thermal stability is also required for metal gate electrode since the metal gate electrode needs to undergo a dopant activation annealing process for the formation of source and drain regions, which occurs at a high temperature during CMOS fabrication.

However, pure metals like hafnium (Hf), tantalum (Ta), titanium (Ti) and their alloys, which typically possess low work function values compatible for n-MOSFET, show limited thermal stability, exhibit excessive gate leakage current and significant degradations in reliability and yields after thermal processing because these metals are fundamentally reactive.

On the other hand, metal nitrides such as tantalum nitride (TaN), titanium nitride (TiN) and hafnium nitride (HfN) have been extensively investigated as potential gate electrode materials due to their good thermal stability. The disadvantage is that each of their respective work functions is close to the silicon mid-gap position.

Therefore, there is a need to find a thermally stable material, with the desired work function, for use as the metal gate electrode in CMOS applications.

### SUMMARY

According to a first aspect of the present invention there is provided a gate electrode for semiconductor devices, the gate electrode comprising a mixture of a metal having a work function of about 4 eV or less and a metal nitride.

The metal having a work function of about 4 eV or less may comprise a lanthanide metal.

The lanthanide metal may comprise any one or more of a group consisting of Tb, Yb, Dy and Er.

The metal having a work function of about 4 eV or less may comprise any one or more of a group consisting of Hf, La, Y and Nb.

The metal nitride may comprise any one or more of a group consisting of TaN, TiN, HfN and WN.

The gate electrode may further comprise a capping layer.

The capping layer may comprise any one or more of a group consisting of TaN, TiN, HfN, W, WN and polycrystalline silicon.

The gate electrode may have a work function of about 4.0 eV to about 4.4 eV after being annealed to about 420° C. or more.

The gate electrode may have a work function of about 4.0 eV to about 4.4 eV after being annealed to about 1000° C.

The gate electrode may further comprise a thin gate dielectric layer.

The thin gate dielectric layer may comprise SiO₂, or SiON.

The thin gate dielectric layer may comprise a material with a high dielectric constant, k, from about 10 to about 30.

The material with a high dielectric constant, k, from about 10 to about 30, may comprise any one or more of a group consisting of ZrO₂, HfO₂, Al₂O₃, Ta₂O₅, HfAlO, HfON, HfSiON and HfSiO.

According to a second aspect of the present invention there is provided a method of fabricating a gate electrode for semiconductor devices, the method comprising forming a mixture of a metal having a work function of about 4 eV or less and a metal nitride.

The mixture of the metal having a work function of about 4 eV or less and the metal nitride may be directly formed using any one or more processes of a group consisting of PVD, CVD and ALCVD.

The method may comprise forming a layer of the metal nitride; and followed by incorporating the metal with the work function of about 4.0 eV or less into the metal nitride layer.

The metal nitride may be formed using any one or more processes of a group consisting of PVD, CVD and ALCVD.

The metal with the work function of about 4.0 eV or less may be incorporated into metal nitride material using any ion implantation or inter-diffusion.

The gate electrode may have a work function of about 4.0 eV to about 4.4 eV after being annealed to about 420° C. or more.

The gate electrode may have a work function of about 4.0 eV to about 4.4 eV after being annealed to about 1000° C.

The metal having the work function of about 4 eV or less may comprise a lanthanide metal.

The lanthanide metal may comprise any one or more of a group consisting of Tb, Yb, Dy and Er.

The metal having a work function of about 4 eV or less may comprise any one or more of a group consisting of Hf, La, Y and Nb.

The metal nitride may comprise any one or more of a group consisting of TaN, TiN, HfN and WN.

The method may comprise forming a capping layer above the mixture of the metal having the work function of about 4 eV or less and the metal nitride.

The capping layer may be formed using any one or more processes of a group consisting of PVD, CVD and ALCVD.

The capping layer may comprise any one or more of a group consisting of TaN, TiN, HfN, W, WN and polycrystalline silicon.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1 is a cross-sectional structural view of a CMOS transistor built in accordance with an embodiment of the present invention.

FIGS. 2a to 2f are cross-sectional structural views of stages of a CMOS fabrication according to an embodiment of the present invention.

FIG. 3 is a plot showing the X-Ray Diffraction (XRD) spectra for tantalum terbium nitride (Ta₁₋ₓTbₓN_{y}) with different terbium (Tb) concentrations.

FIG. 4a is a plot showing flat band voltage (V_{FB}) against effective gate oxide thickness (EOT) to extract the work function for different metal nitrides and different metal nitrides with an incorporated lanthanide metal after Forming Gas Anneal (FGA) at 420° C.

FIG. 4b is a plot showing V^{FB} against EOT to extract the work function for different metal nitrides and different metal nitrides with an incorporated lanthanide metal after 1000° C. rapid thermal annealing (RTA)

FIG. 5 shows a plot of the effective work functions (eV) for different metal nitrides and lanthanide incorporated metal nitrides under different annealing conditions.

FIG. 6 are cross-sectional transmission electron microscopy (XTEM) images of Ta_{0.94}Tb_{0.06}N_{y} used above a silicon dioxide (SiO₂) thin gate dielectric layer on a 100-alignment Si substrate after different thermal treatment.

FIG. 7 is a plot of Delta EOT (nm) against the content of Tb in Ta₁₋ₓTbₓN_{y} that shows the EOT stability of a Ta₁₋ₓTbₓN_{y}/SiO₂ gate region after 1000° C. RTA for 20 seconds.

FIG. 8 shows the Weibull distribution plots against the time to breakdown (sec) for a gate electrode comprising comprising Ta_{0.94}Tb_{0.06}N_{y} above a SiO₂ thin gate dielectric layer, according to an embodiment of the present invention.

FIG. 9 is a plot of gate leakage (A/cm²) against gate voltage-flatband voltage (V_{G}-V_{FB}) (V) showing the respective I-V characteristics of a gate electrode comprising Ta_{0.94}Tb_{0.06}N_{y} on a SiO₂ thin gate electrode and a gate electrode comprising tantalum erbium nitride (Ta_{0.95}Er_{0.05}N_{y}) on a SiO₂ thin gate electrode after annealing at different temperatures.

FIG. 10 is a plot of capacitance density (fF/μm²) against gate voltage (V) that compares the capacitance-voltage (C-V) characteristics of MOS capacitors using hafnium aluminum oxide (HfAlO) dielectric where TaN is used in one embodiment against another embodiment where Ta_{0.9}Tb_{0.1}N_{y} is used.

### DETAILED DESCRIPTION

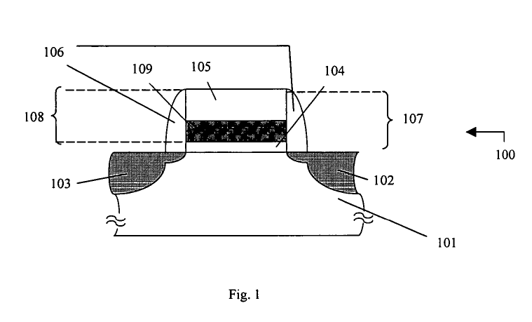

FIG. 1 illustrates a cross-sectional structural view of a CMOS transistor 100 fabricated in accordance with one embodiment of the invention. The CMOS transistor 100 in the embodiment shown in FIG. 1 comprises a substrate 101, a source region 103, a gate 107, a drain region 102 and dielectric spacers 106. Silicon, for example, is used as the material for the substrate 101, while the source region 103 and the drain 102 region for instance comprise silicon doped with phosphorus (P) or arsenic (As). The dielectric spacers 106 comprise SiO₂ or Si₃N₄ in the example embodiment.

The gate 107 comprises of two regions; firstly a thin gate dielectric layer 104, which is located directly above the substrate 101, and secondly, a gate electrode 108, which is located directly above the thin gate dielectric layer 104. The material used for the thin gate dielectric layer 104 is for example, SiO₂, or silicon oxynitride (SiON), or dielectrics with a high dielectric constant, k (e.g. from about 10 to about 30), such as zirconium oxide (ZrO₂), HfO₂, Al₂O₃, tantalum pentoxide (Ta₂O₅), HfAlO, HfON, HfSiON and HfSiO, and is often referred to as the gate-oxide layer.

In this embodiment, the gate electrode 108 comprises two layers; the first layer being a metallic layer 109, which is located directly above the thin gate dielectric layer 104; and the second layer being a capping layer 105, which is directly above the metallic layer 109. The metallic layer 109 in this embodiment comprises of a mixture of a low work function metal with work function value of about 4.0 eV or less and a metal nitride. Examples for the low work function metal include a lanthanide metal like terbium (Tb), ytterbium (Yb), dysprosium (Dy), erbium (Er), or other low work function metals such as hafnium (Hf), lanthanum (La), yttrium (Y) or niobium (Nb), while examples for the metal nitride include tantalum nitride (TaN), titanium nitride (TiN), hafnium nitride (HfN) and tungsten nitride (WN). The capping layer 105 comprises, for example, TaN, TiN, HfN, W, WN, polycrystalline silicon or other thermally stable materials. In this embodiment, the capping layer 105 reduces the resistance of the gate 107 and prevents oxidation of the surface of the gate 107. Further, the capping layer 105 provides compatibility for the subsequent manufacturing processes that the semiconductor device 100 may undergo, which are not shown, especially when the capping layer 105 comprises poly-Si.

The metallic layer 109 while serving to determine the work function of the gate electrode 208, also acts as an additional diffusion barrier to oxygen.

The capping layer 105 reduces the gate sheet resistance and protects the top surface of metallic layer 109 from being oxidised when the CMOS transistor 100 is exposed to high temperatures.

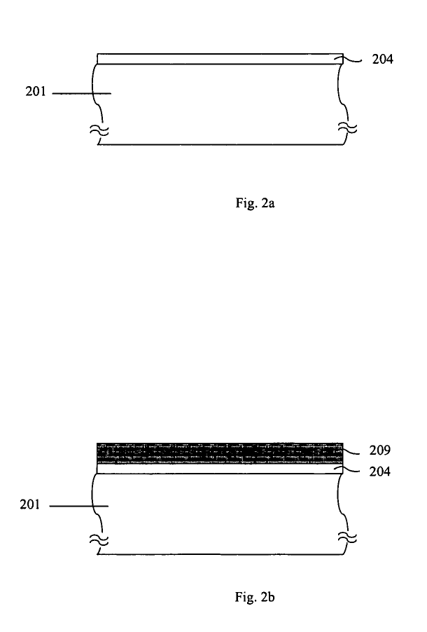

The various stages involved in fabricating a semiconductor device (for example, the CMOS transistor depicted in FIG. 1) according to an embodiment of the invention will now be described with reference to FIGS. 2a to 2f.

In the first stage of the fabrication process, isolation N-well and P-well regions, along with punchthrough and threshold voltage adjustment implantations, all of which are not shown, may be formed within a substrate 201 by known techniques. The process begins with the formation of a gate dielectric 204 on a substrate 201 by known techniques.

A thin gate dielectric layer 204 is blanket deposited or thermally grown on the substrate 201 as shown in FIG. 2a. This deposition is performed, for example but not limited to, by chemical vapour deposition (CVD) or atomic layer deposition (ALD). Silicon, for example, is used for the substrate 201, while the thin gate dielectric layer 204 comprises, for example, SiO₂, SiON, or other dielectrics with a high dielectric constant, k (e.g. from about 10 to about 30), such as zirconium oxide (ZrO₂), HfO₂, Al₂O₃, tantalum pentoxide (Ta₂O₅), HfAlO, HfON, HfSiON and HfSiO.

The next stage of the fabrication process involves the formation of a metallic layer 209 above the thin gate dielectric layer 204 as shown in FIG. 2b. The metallic layer 209 comprises a mixture of a low work function metal, having a work function of about 4.0 eV or less, and a metal nitride. The low work function metal comprises, for example, a lanthanide metal like terbium (Tb), ytterbium (Yb), dysprosium (Dy), erbium (Er), or other low work function metals such as hafnium (Hf), lanthanum (La), yttrium (Y) or niobium (Nb), while the metal nitride can, for example, comprise tantalum nitride (TaN), titanium nitride (TiN), hafnium nitride (HfN) and tungsten nitride (WN).

In one embodiment, the metallic layer 209 is accomplished by directly depositing the mixture of the low work function metal and the metal nitride above the thin gate dielectric layer 204 to form the metallic layer 209. This deposition is achieved through methods that include, but are not limited to, physical vapor deposition (PVD), chemical vapor deposition (CVD) and atomic layer chemical vapor deposition (ALCVD). In one embodiment, the PVD is performed at a chamber pressure of about 1 to about 3 mTorr and at room temperature. In one embodiment the mixture is Ta₁₋ₓTbₓN_{y} which is formed by co-sputtering of Tb at an electrical power of 150 W and Ta at an electrical power of 450 W on the respective targets in the ambient gases N₂ and Ar with flow rates at 5 and 25 sccm respectively. However, the PVD can also be performed under different conditions.

In another embodiment, a metal nitride layer is first deposited above the thin gate dielectric layer 204. This deposition can be achieved through methods that include, but are not limited to, physical vapor deposition (PVD), CVD and atomic layer chemical vapor deposition (ALCVD). This deposition is then followed by the incorporation, e.g. by implantation, of the low work function metal into the metal nitride by materials such as, but not limited to, a lanthanide metal like terbium (Tb), ytterbium (Yb), dysprosium (Dy), erbium (Er), or other low work function metals such as hafnium (Hf), lanthanum (La), yttrium (Y) or niobium (Nb).

In another embodiment, the metallic layer 209 is formed by depositing a layer of the metal nitride directly above the thin gate dielectric layer 204, followed by a layer of the low work function metal directly above the layer of the metal nitride. The deposition of the two layers can be achieved through methods that include, but are not limited to, physical vapor deposition (PVD), CVD and atomic layer chemical vapor deposition (ALCVD). Subsequently the low work function metal is interdiffused in the layer of the metal nitride by an alloying process, for example, RTA at about 900° C. to about 1000° C. for about 10 to about 30 sec.

The incorporated low work function metal provides a mechanism to adjust the work function of the metallic layer 209 to a desired value by varying the concentration and type of the low work function metal used. It was found that the work function of the resulting gate electrode remained at a low level of around 4.2 to around 4.3 eV even after the gate electrode was annealed to a temperature of about 1000° C. The incorporated low work function metal was also found to modify the structure of the metal nitride present and improve the properties of the resulting gate electrode, for example, serving as a good O₂ diffusion barrier. It was also found that the presence of N in the mixture of the low work function metal and the metal nitride provided for the mixture to have good thermal and chemical stability as well as a stable interface with the thin gate dielectric layer 204. A typical concentration of the low work function metal in the mixture is above about 50%. In an embodiment it was observed that the gate leakage current and gate dielectric reliability did not degrade even after the resulting gate electrode was annealed to a temperature of about 1000° C. as compared to another embodiment that underwent forming gas anneal (FGA) at 420° C.

The thickness of the metallic layer 209 should preferably be great enough to determine the work function of the resulting gate electrode. However, the metallic layer 209 should also preferably be thin enough to prevent under cutting of the metallic layer 209 if a wet etching process is used to pattern the resulting metallic layer 209. A typical thickness would be from about 50 Å to about 200 Å.

An in-situ capping layer 205 is next deposited directly above the metallic layer 209, as shown in FIG. 2c. Materials such as TaN, TiN, HfN, W, WN, polycrystalline silicon or other thermally stable materials are used for the capping layer 205 in example embodiments. In other embodiments, a bi-layer structure, such as poly-silicon capped TiN or TaN can be used for the capping layer 205. The thickness of the capping layer 205 in an example embodiment is about 1000 Å.

Deposition of the capping layer 205 in the example embodiment is accomplished by, but not limited to, PVD, CVD and ALCVD.

The capping layer 205 acts to protect the top surface of metallic layer 209 from being oxidised and acts to reduce the gate sheet resistance in this embodiment of the invention. Further, the capping layer 205 acts as a barrier to prevent ionised dopants, which are introduced during the subsequent ion-implantation processes shown in FIGS. 2e to 2f, from entering the metallic layer 209 and substrate 201 region that is directly below the gate 207. It is desirable that the capping layer 205 exhibit good thermal and chemical stability in the subsequent stages shown in FIGS. 2d to 2f of the fabrication process.

The metallic layer 209 is preferably not too thick as the metallic layer 209 is difficult to etch by dry etching. For example, the thickness of metallic layer 209 in an embodiment is about 50 Å to about 200 Å. Therefore, the capping layer 205, which is easier to etch than the metallic layer 209, provides another advantage of build-up to a desired resulting gate structure thickness of about 1000 Å to about 1500 Å in an example embodiment.

In the following stage of the fabrication process, the metallic layer 209, the capping layer 205 and the thin gate dielectric layer 204 are patterned and etched to form the gate electrode 208 and the gate 207 as shown in FIG. 2d.

The capping layer 205 and the metallic layer 209 are, in one embodiment, first etched using a plasma dry-etch method to achieve the desired pattern. This is followed by a wet etch of the exposed thin gate dielectric layer 204 to achieve the desired pattern.

In another embodiment, the capping layer 205 is first etched using a plasma dry-etch method to achieve the desired pattern, followed by a wet-etch of the metallic layer 209 and the thin gate dielectric layer 204 to achieve the desired pattern. The wet-etch removal of the metallic layer 209 and the thin gate dielectric layer 204 can provide the advantage of minimising damage to the exposed region of the substrate 201 where the source and drain regions are to be subsequently formed.

In the next stage of the fabrication process, the substrate 201 undergoes ion implantation to form a shallow doped drain 202a region and a shallow doped source 203a region shown in FIG. 2e using known techniques. Examples of dopants that are used include P and As for NMOS devices.

In the final stage of the fabrication process, dielectric spacers 206 are deposited, for example, by Plasma Enhanced Chemical Vapor Deposition (PECVD) or Low Presure Chemical Vapor Deposition (LPCVD) using known techniques. A deeper source 203 region and a deeper drain 202 region are formed, for example, through a second ion implantation using for example, P or As for NMOS devices and a high temperature anneal process such as 1050° C. spike annealing to activate the dopants in source and drain regions, using known techniques. The resulting CMOS transistor 200 is shown in FIG. 2f.

The transistor 200 can now be further processed in accordance with any one of the conventional CMOS fabrication methods to produce completed transistors.

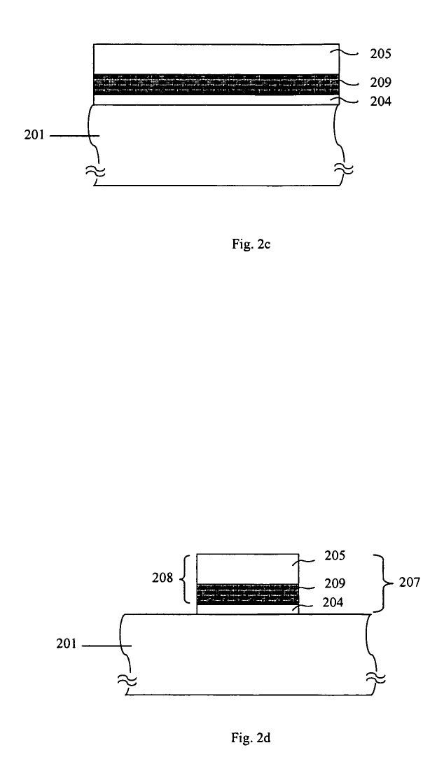

In the following paragraphs, experimental results are discussed illustrating features of different MOS capacitor embodiments of the present invention with reference to FIGS. 3 to 10.

FIG. 3 shows a plot of intensity (a.u.) against 2θ (degree) for different metallic gate layers. For comparison, curves 300 representing TaN only is plotted against the other curves 301, 302, 303 and 304 respectively representing Ta₁₋ₓTbₓN_{y} with different Tb concentrations for different embodiments. Each set of curves 300, 301, 302, 303 and 304 represent two X-Ray Diffraction (XRD) spectra, one being the spectrum obtained from the metallic gate layer without any annealing (represented by an unbroken line), while the other is the spectrum obtained after the metallic layer is annealed at 1000° C. for 20 seconds (represented by a broken line). From the spectra, it can be observed that by incorporating Tb at a fraction of Tb/(Ta+Tb) above 0.06, the crystallisation of TaN is significantly retarded and the Ta₁₋ₓTbₓN_{y} metallic layer kept amorphous up to a temperature of 1000° C. The retardation of TaN crystallinity at the higher Tb concentration may be due to the break down of the periodic arrangement of atoms in TaN by the Tb atoms which have larger atomic radius.

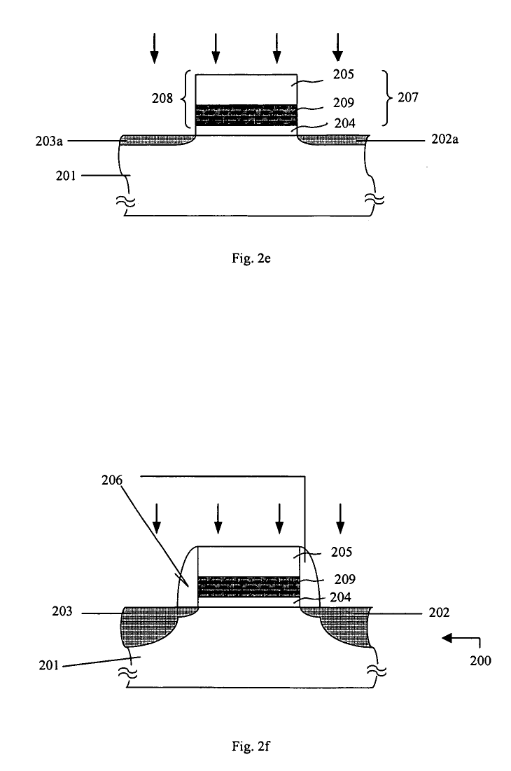

FIG. 4a shows plots of the flat band voltage V_{FB} against the effective gate-oxide thickness (EOT) after a Forming Gas Anneal (FGA) process at 420° C. for 30 minutes, where SiO₂ was used as the dielectric layer. Curves 401 and 402 show the results obtained for gate electrodes comprising only HfN and TaN respectively. On the other hand, curves 403, 404 and 405 show the results obtained for embodiments of the gate electrode comprising Hf_{0.8}Tb_{0.2}N_{y}, Ta_{0.95}Er_{0.05}N_{y} and Ta_{0.94}Tb_{0.06}N_{y} respectively. The work function value for HfN, TaN, Hf_{0.8}Tb_{0.2}N_{y}, Ta_{0.95}Er_{0.05}N_{y} or Ta_{0.94}Tb_{0.06}N_{y} can be obtained from each of the respective curves shown. The work function value can be obtained from the formula
V_{FB}=Φ_{MS}−Qₒₓ/Cₒₓ=Φ_{MS}−(Qₒₓ·EOT)/(εₒ·εₒₓ) (1)
where Φ_{MS} is the work function difference between Si and the metal gate, Qₒₓ is the equivalent oxide charges at the interface between dielectric and Si, εₒₓ is the permittivity of SiO₂ and εₒ is the permittivity of free space. The value of V_{FB} can be found by setting EOT=0 in equation (1) (i.e. Φ_{MS}=V_{FB|EOT=0},) where Φ_{MS} will be intercept of the various graphs 401-405 on the vertical axis. In this embodiment where the work function of Si is 4.95 eV, the work function of each of the metallic layers 209 for curves 401-405 can therefore be calculated.

From FIG. 4a, it can be seen that the incorporation of the lanthanide metal into the metal nitride lowers the work function of the resulting gate electrode. For example, the work function of the gate electrode that only comprises HfN is 4.65 eV, while the work function of the gate electrode that comprises HfTbN is 4.23 eV.

FIG. 4b shows plots of the flat band voltage V_{FB} against the effective gate-oxide thickness (EOT) after a Rapid Thermal Annealing (RTA) process at 1000° C. for about 10 seconds to about 30 seconds, where SiO₂ was used as the dielectric layer. Curves 406 and 407 show the results obtained for gate electrodes comprising only HfN and TaN respectively. On the other hand, curves 408, 409 and 410 show the results obtained for embodiments of the gate electrode comprising Hf_{0.8}Tb_{0.2}N_{y}, Ta_{0.95}Er_{0.05}N_{y} and Ta_{0.94}Tb_{0.06}N_{y} respectively. The work function value for HfN, TaN, Hf_{0.8}Tb_{0.2}N_{y}, Ta_{0.95}Er_{0.05}N_{y} or Ta_{0.94}Tb_{0.06}N_{y} can be obtained from each of the respective curves shown.

From FIG. 4b, it can be seen that the incorporation of the lanthanide metal into the metal nitride lowers the work function of the resulting gate electrode, even if the incorporated mixture is exposed to a higher temperature when compared to the results presented in FIG. 4a. For example, the work function of the gate electrode that only comprises HfN is 4.71 eV, while the work function of the gate electrode that comprises HfTbN is 4.31 eV.

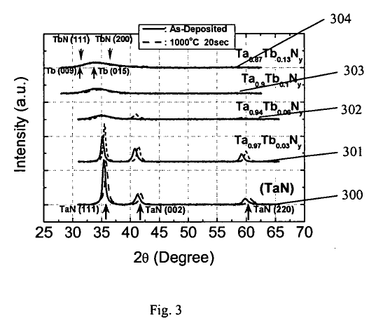

FIG. 5 shows a plot of the effective work functions (eV) for different metal nitrides and lanthanide incorporated metal nitrides under annealing conditions of 420° C., 800° C., 900° C. and 1000° C. The 420° C. anneal was performed for about 30 minutes, the 800° C. and 900° C. anneals were performed for about 20 seconds to about 30 seconds and the 1000° C. anneal was performed for about 10 seconds to about 30 seconds. The concentration of the materials of TaN, Ta_{0.97}Tb_{0.03}N_{y}, Ta_{0.94}Tb_{0.06}N_{y}, Ta_{0.9}Tb_{0.1}N_{y}, Ta_{0.87}Tb_{0.13}N_{y}, Ta_{0.97}Er_{0.03}N_{y}, Ta_{0.95}Er_{0.05}N_{y}, Ta_{0.97}Yb_{0.03}N_{y}, HfN, Hf_{0.89}Tb_{0.11}N_{y} and Hf_{0.8}Tb_{0.2}N_{y} were determined by X-ray Photoelectron Spectroscopy (XPS) analysis. As shown in FIG. 5, it can be seen that different work functions are achieved when different concentrations of the respective lanthanide metal are used. Further, the respective work function of each material shows only a slight variation when the same material is subjected to different annealing temperatures. Thus, the work function of the gate electrode 208 can be adjusted by adjusting the concentration of the respective lanthanide metal that is incorporated with the metal nitride, in example embodiments.

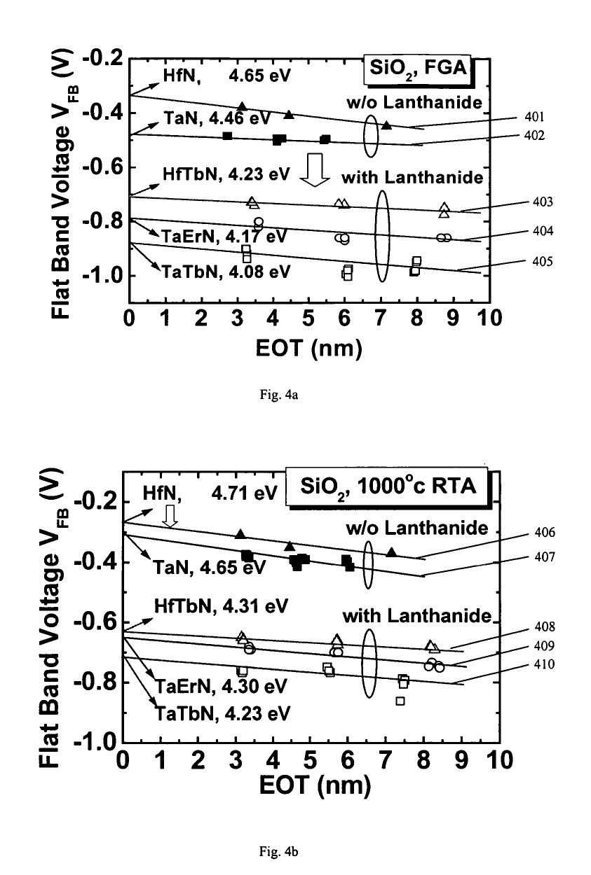

FIG. 6 shows cross-sectional transmission electron microscopy (XTEM) images of Ta_{0.94}Tb_{0.06}N_{y} used as gate electrodes on a SiO₂ thin gate dielectric layer on a (100)-alignment Si substrate after different thermal treatments at 420° C., 900° C. and 1000° C. as shown respectively by numerals 601, 602 and 603. The 420° C. anneal was performed for about 30 minutes, the 900° C. anneal was performed for about 30 seconds and the 1000° C. anneal was performed for about 30 seconds. The EOT stability of the Ta_{0.94}Tb_{0.06}N_{y}/SiO₂ gate region can thus be appreciated.

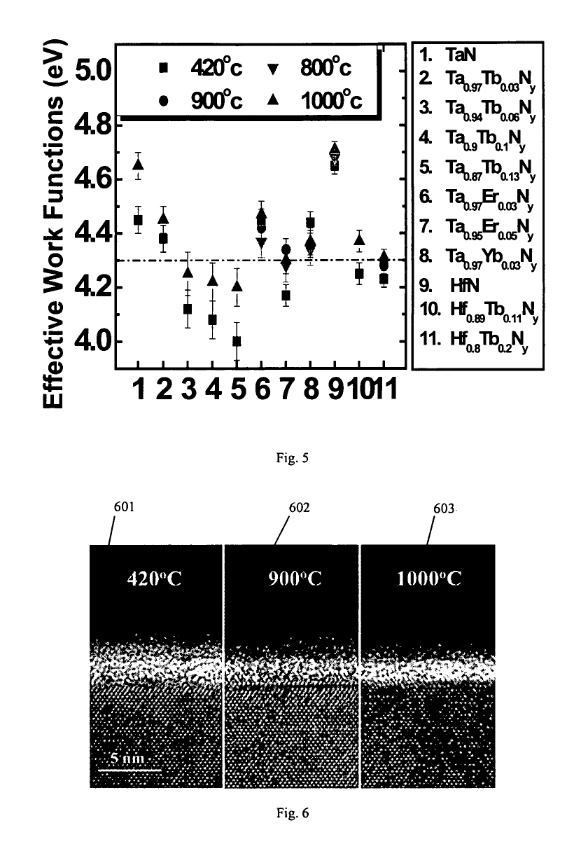

FIG. 7 shows a plot of Delta EOT (nm) against the content of Tb in Ta₁₋ₓTbₓN_{y} after 1000° C. RTA for about 20 seconds. The graph 700 shows the EOT variation of a Ta_{0.94}Tb_{0.06}N/SiO₂ gate region as a function of Tb sputtering power. There is an improvement in the EOT stability, as indicated by the embodiments, after Tb was incorporated with TaN, attributing to the good O₂ diffusion barrier property of Ta_{0.94}Tb_{0.06}N_{y} during thermal annealing of up to around 1000° C.

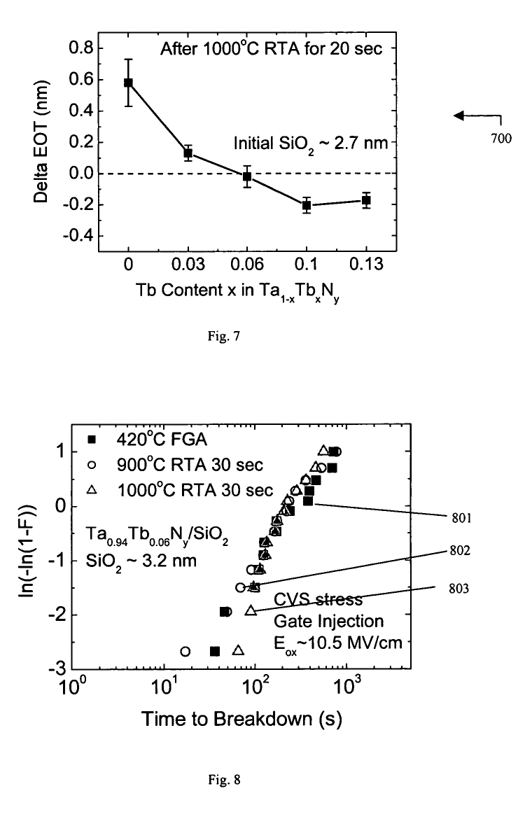

FIG. 8 shows the Weibull distribution function plots against the time to breakdown (sec) for a gate electrode comprising Ta_{0.94}Tb_{0.06}N_{y} above a SiO₂ thin gate dielectric layer of approximately 3.2 nm thickness after anneal at 420° C., 900° C. and 1000° C. The 420° C. FGA (curve 801) was performed for about 30 minutes, the 900° C. RTA was performed for about 30 seconds (curve 802) and the 1000° C. RTA was performed for about 30 seconds (curve 803). These measurements were carried out under constant voltage stress (CVS) in gate injection condition. It is found that the Time Dependent Dielectric Breakdown (TDDB) characteristics of the gate stack did not show degradation even under the higher temperature 1000° C. RTA process, indicating the good thermal stability of the Ta_{0.94}Tb_{0.06}N_{y}/SiO₂ interface.

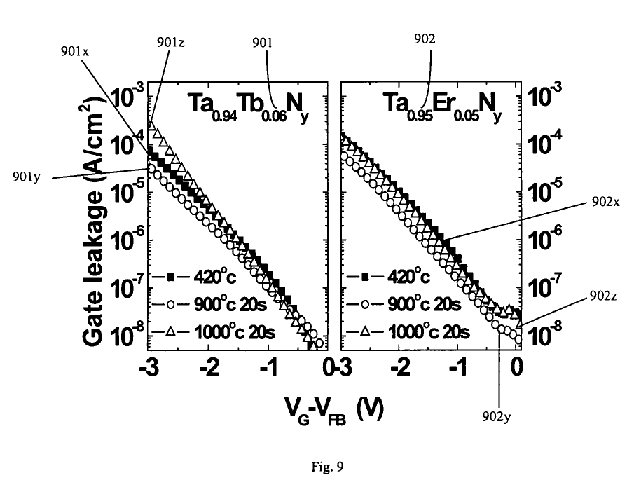

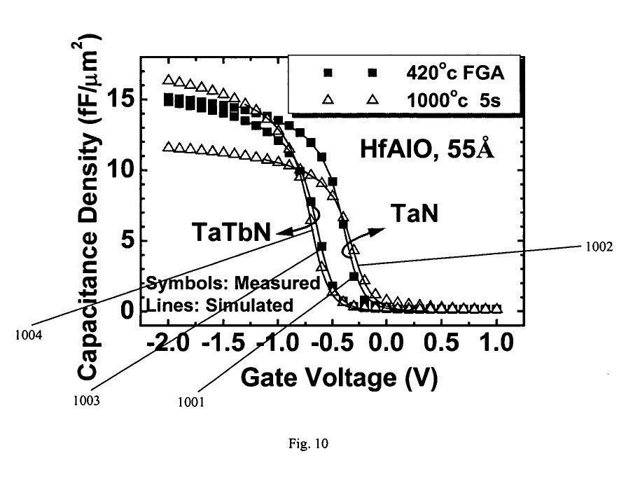

FIG. 9 plots the gate leakage (A/cm²) against V_{G}-V_{FB} and compares the graphs obtained for a gate region comprising a SiO₂ thin gate dielectric layer and a Ta_{0.94}Tb_{0.06}N_{y} metallic layer (graph 901) against a gate region comprising a SiO₂ thin gate dielectric layer and a Ta_{0.95}Er_{0.05}N_{y} metallic layer (graph 902). The samples were subjected to a 420° C. FGA (curves 901x and 902x) for about 30 minutes, a 900° C. RTA for about 20 seconds (curves 901y and 902y) and a 1000° C. RTA for about 20 seconds (curves 901z and 902z). As shown in FIG. 10, the gate leakage exhibits thermal stability.

FIG. 10 shows plots of capacitance density (fF/μm²) against gate voltage (V) to compare the capacitance-voltage (C-V) characteristic curves of MOS capacitors using a HfAlO dielectric where TaN is used as a reference (curves 1001 and 1002) against another embodiment where Ta_{0.09}Tb_{0.1}N_{y} is used (curves 1003 and 1004). The two different test conditions are a 420° C. FGA for about 30 minutes (curves 1001 and 1003) and a 1000° C. RTA for about 5 seconds (curves 1002 and 1004). The embodiment comprising Ta_{0.9}Tb_{0.1}N_{y} shows a lower flatband voltage compared to the reference using TaN due to the lower work function of Ta_{0.9}Tb_{0.1}N_{y}.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

1. A gate electrode for semiconductor devices, the gate electrode comprising a mixture of a metal having a work function of about 4 eV or less and a metal nitride.

2. The gate electrode according to claim 1, wherein the metal having a work function of about 4 eV or less comprises a lanthanide metal.

3. The gate electrode according to claim 2, wherein the lanthanide metal comprises any one or more of a group consisting of Tb, Yb, Dy and Er.

4. The gate electrode according to claim 1, wherein the metal having a work function of about 4 eV or less comprises any one or more of a group consisting of Hf, La, Y and Nb.

5. The gate electrode according to claim 1, wherein the metal nitride comprises any one or more of a group consisting of TaN, TiN, HfN and WN.

6. The gate electrode according to claim 1, wherein the gate electrode further comprises a capping layer.

7. The gate electrode according to claim 6, wherein the capping layer comprises any one or more of a group consisting of TaN, TiN, HfN, W, WN and polycrystalline silicon.

8. The gate electrode according to claim 1, wherein the gate electrode has a work function of about 4.0 eV to about 4.4 eV after being annealed to about 420° C. or more.

9. The gate electrode according to claim 1, wherein the gate electrode has a work function of about 4.0 eV to about 4.4 eV after being annealed to about 1000° C.

10. The gate electrode according to claim 1, wherein the gate electrode forms part of a gate of the semiconductor device, and the gate electrode is formed on a thin gate dielectric layer.

11. The gate electrode according to claim 10, wherein the thin gate dielectric layer comprises SiO₂, or SiON.

12. The gate electrode according to claim 10, wherein the thin gate dielectric layer comprises a material with a high dielectric constant, k, from about 10 to about 30.

13. The gate electrode according to claim 12, wherein the material with a high dielectric constant, k, from about 10 to about 30, comprises any one or more of a group consisting of ZrO₂, HfO₂, Al₂O₃, Ta₂O₅, HfAlO, HfON, HfSiON and HfSiO.

14. A method of fabricating a gate electrode for semiconductor devices, the method comprising forming a mixture of a metal having a work function of about 4 eV or less and a metal nitride.

15. The method according to claim 14, wherein the mixture of the metal with the work function of about 4.0 eV or less and the metal nitride is directly formed using any one or more processes of a group consisting of PVD, CVD and ALCVD.

16. The method according to claim 14, comprising:
forming a layer of the metal nitride; and followed by incorporating the metal with the work function of about 4.0 eV or less into the metal nitride layer.

17. The method according to claim 16, wherein the metal nitride is formed using any one or more processes of a group consisting of PVD, CVD and ALCVD.

18. The method according to claim 16, wherein the metal with the work function of about 4.0 eV or less is incorporated using ion implantation or interdiffusion.

19. The method according to claim 14, wherein the gate electrode has a work function of about 4.0 eV to about 4.4 eV after being annealed to about 420° C. or more.

20. The method according to claim 19, wherein the gate electrode has a work function of about 4.0 eV to about 4.4 eV after being annealed to about 1000° C.

21. The method according to claim 14, wherein the metal having the work function of about 4 eV or less comprises a lanthanide metal.

22. The method according to claim 21, wherein the lanthanide metal comprises any one or more of a group consisting of Tb, Yb, Dy and Er.

23. The method according to claim 14 wherein the metal having a work function of about 4 eV or less comprises any one or more of a group consisting of Hf, La, Y and Nb.

24. The method according to claim 14, wherein the metal nitride comprises any one or more of a group consisting of TaN, TiN, HfN and WN.

25. The method according to claim 14, comprising:
forming a capping layer above the mixture of the metal having the work function of about 4 eV or less and the metal nitride.

26. The method according to claim 25, wherein the capping layer is formed using any one or more processes of a group consisting of PVD, CVD and ALCVD.

27. The method according to claim 25, wherein the capping layer comprises any one or more of a group consisting of TaN, TiN, HfN, W, WN and polycrystalline silicon.
